(19) United States
(12) Patent Application Publication
(10) Pub. No.: US 2013/0092955 A1
(43) Pub. Date: Apr. 18, 2013

(54) LIGHT EMITTING DIODE AND FABRICATING METHOD THEREOF

(71) Applicants: Shin-Jia Chiou, Tainan (TW); Chung Hsin Lin, Tainan (TW); Chi-Lung Wu, Tainan (TW); Jui-Chun Chang, Tainan (TW)

(72) Inventors: Shin-Jia Chiou, Tainan (TW); Chung Hsin Lin, Tainan (TW); Chi-Lung Wu, Tainan (TW); Jui-Chun Chang, Tainan (TW)

(73) Assignee: CHI MEI LIGHTING TECHNOLOGY CORP., Tainan (TW)

(21) Appl. No.: 13/403,734

(22) Filed: Feb. 23, 2012

(30) Foreign Application Priority Data
Oct. 18, 2011 (TW) 100137779

(51) Int. Cl. H01L 33/06; H01L 33/32; H01L 33/34; H01L 33/10

(52) U.S. Cl. 257/77; 438/29; 257/98; 257/76; 257/E33.008; 257/E33.068; 257/E33.025; 257/E33.035

(57) ABSTRACT

A light-emitting diode (LED) and fabricating method thereof. The method includes: providing a first substrate and forming an epitaxial portion on the first substrate; forming at least one reflection layer on the epitaxial portion; forming a metal barrier portion on the reflection layer; etching the epitaxial portion and the barrier portion by a first etching process, so as to form a plurality of epitaxial layers and a plurality of metal barrier layers, an etch channel is formed between adjacent epitaxial layers, and each metal barrier layer enwraps a corresponding reflection layer and covers all of a surface of a corresponding epitaxial layer; forming a first bonding layer on the metal barrier layer; and forming a second substrate on the first bonding layer and removing the first substrate.

### CROSS-REFERENCE TO RELATED APPLICATIONS

This non-provisional application claims priority under 35 U.S.C. §119(a) on Patent Application No. 100137779 filed in Taiwan R.O.C. on Oct. 18, 2011, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates to a light emitting diode and a fabricating method thereof, and more particularly to a light emitting diode and a fabricating method thereof, where an isolation layer may be disposed to completely cover a surface of an epitaxial layer so as to prevent cracking of edges of the epitaxial layer during a laser lift-off process.

### BACKGROUND OF THE INVENTION

In a conventional light emitting diode having a horizontal structure, as two electrodes need to be disposed at the same side of an epitaxial structure, the effective light-emitting area is small and the current flow path is long, leading to a high series resistance, and resulting in serious current crowding effect. When in operation under high-power operation, the light emitting diode having a horizontal structure easily generates a high temperature, which reduces the luminance and luminous efficiency, changes light emitting wavelengths, degrades the reliability, and shortens the service life of the light emitting diode. To overcome the above defects, a vertical light emitting diode having a vertical structure is developed.

FIGS. 1(a) and 1(b) show a cutting flow of a conventional vertical light emitting diode. The conventional light emitting diode 1 shown in FIG. 1(b) includes a substrate 101, a first bonding layer 102, a reflection layer 103, an epitaxial (EPI) layer 104, and a second bonding layer 105 disposed on the substrate 101 and used for being bonded to the first bonding layer 102. In the cutting process shown in FIG. 1(a) to FIG. 1(b), to obtain the conventional vertical light emitting diode 1, a wafer having multiple conventional vertical light emitting diodes in FIG. 1(a) needs to be subjected to a laser lift-off process for removing an aluminum oxide substrate and a wafer cutting process. Therefore, when a laser is focused on an interface between the aluminum oxide (Al₂O₃) substrate and the epitaxial layer 104, the epitaxial layer at the interface may dissociation to generate gallium (Ga) atoms and nitrogen (N₂) gas. In this case, an etched channel needs to be formed first, so that the gas may be discharged through the etched channel. However, in such a process, edges of the epitaxial layer 104 near the junction between the epitaxial layer 104 and the bonding layer 102 easily crack due to the stress generated during the laser lift-off process and discharge of nitrogen gas. Once cracks are generated (as indicated by circles in FIG. 1(b)), a leakage current may further be caused in the light emitting diode, thus reducing the production yield.

In view of that the conventional light emitting diode and fabricating method thereof may not effectively prevent cracking and generation of a leakage current and improve the production yield, it is necessary to propose a novel light emitting diode and fabricating method thereof, which may be used for preventing cracking and generation of a leakage current and improving the production yield.

Therefore, a heretofore unaddressed need exists in the art to address the aforementioned deficiencies and inadequacies.

### SUMMARY OF THE INVENTION

In one aspect, the present invention is directed to a light emitting diode, where an isolation layer may be disposed to completely cover a surface of an epitaxial layer so as to prevent cracking of edges of the epitaxial layer in a laser lift-off process.

In another aspect, the present invention is directed to a method for fabricating a light emitting diode, which may effectively prevent cracking of edges of an epitaxial layer and generation of a leakage current, and improve the production yield.

In one embodiment, a method for fabricating a light emitting diode according to the present invention includes: providing a first substrate, and forming an epitaxial portion on the first substrate; forming at least one reflection layer on the epitaxial portion; forming a metal barrier portion on the reflection layer; etching the epitaxial portion and the metal barrier portion by a first etching process, so as to form a plurality of epitaxial layers and a plurality of metal barrier layers, where an etched channel is formed between adjacent epitaxial layers, and each metal barrier layer wraps a corresponding reflection layer and completely covers a surface of a corresponding epitaxial layer; forming a first bonding layer on the metal barrier layer; and forming a second substrate on the first bonding layer, and removing the first substrate.

In another embodiment, a light emitting diode according to the present invention includes: a substrate; a first bonding layer, formed on the substrate; a metal barrier layer, formed on the first bonding layer; and an epitaxial layer, formed on the metal barrier layer, where a surface of the epitaxial layer is completely covered by the metal barrier layer, and the first bonding layer is slightly smaller than the metal barrier layer.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIGS. 1(a) and 1(b) show a cutting flow of a conventional vertical light emitting diode;

FIGS. 2-6 show a method for fabricating a light emitting diode according to one embodiment of the present invention; and

FIG. 7 is a schematic cross-sectional view of a light emitting diode according to one embodiment of the present invention.

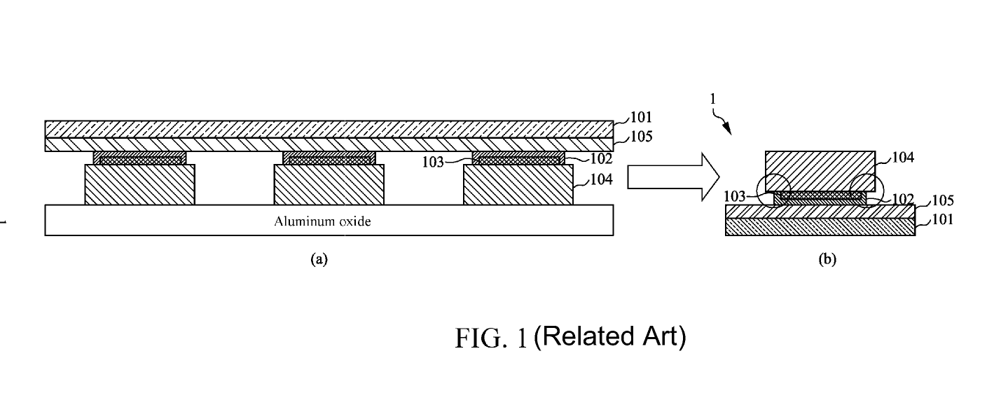

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

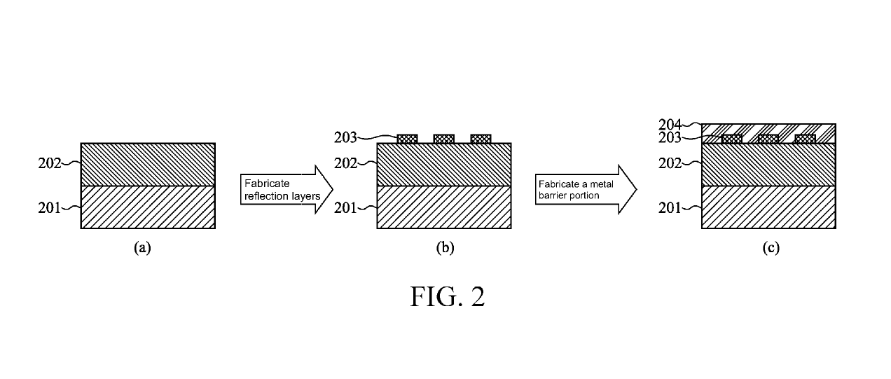

Referring to FIGS. 2-6, a method for fabricating a light emitting diode according to one embodiment of the present invention is provided. As shown in FIG. 2(a), first, a first substrate 201 is provided, and an epitaxial portion 202 is formed on the first substrate 201 by Metal Organic Chemical Vapor Deposition (MOCVD). Next, a metal reflection layer is formed on the epitaxial portion 202 by evaporation or sputtering, and is further subjected to a lithography and etching process, so as to form one or more reflection layers 203 on the epitaxial portion 202 (as shown in FIG. 2(b)). Then, a metal barrier portion 204 is formed on the reflection layers 203 by evaporation or sputtering, where the metal barrier portion 204 may wrap all the reflection layers 203 (as shown in FIG. 2(c)). In this embodiment, the material of the metal barrier portion 204 is a flexible metal, for example, a tungsten titanium alloy, platinum, tungsten or a combination thereof, and the metal barrier portion 204 may also be a combination of multiple layers of the above metals.

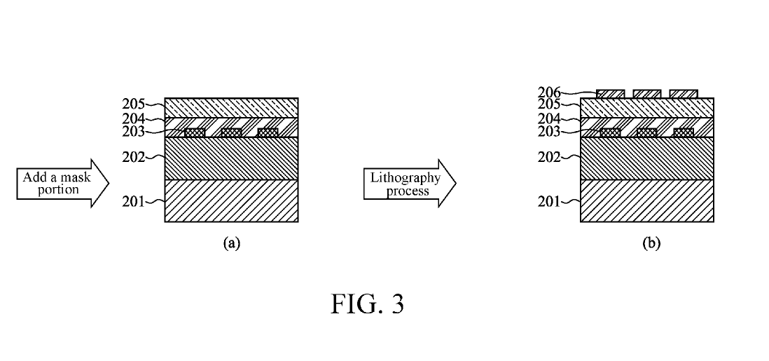

Then, as shown in FIG. 3(a), a metal mask portion 205 is formed on the metal barrier portion 204 by evaporation or sputtering, where the material of the metal mask portion 205 may be, but not limited to, nickel (Ni). Next, one or more patterned photoresist layers 206 are formed from a photoresist material by a lithography process (for example, photo lithography process), and the patterned photoresist layers 206 are used as etch masks of the metal mask portion 205 (as shown in FIG. 3(b)).

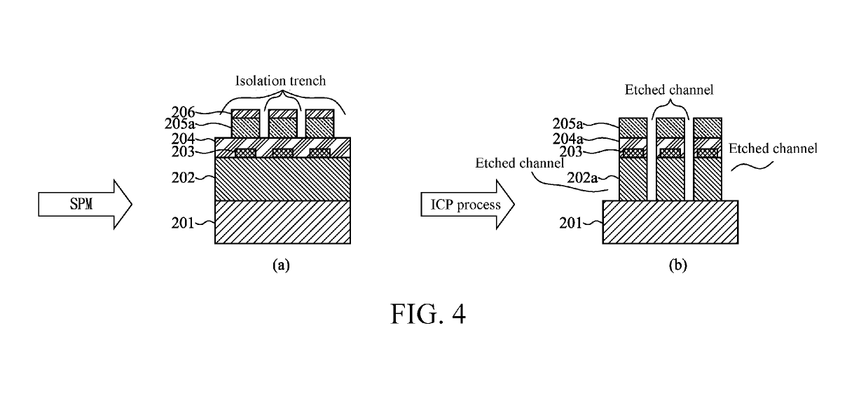

Then, as shown in FIG. 4(a), the metal mask portion 205 not protected by the patterned photoresist layers 206 is etched with an etchant being a mixture (SPM) of sulfuric acid, hydrogen peroxide and water and using the patterned photoresist layers 206 as etch masks, so that each metal mask layer 205a has an isolation trench, thereby patterning the metal mask layers 205a as shown in FIG. 4(a). Preferably, the etchant (SPM) is formed by mixing sulfuric acid, hydrogen peroxide and water at a ratio of 5:1:1. Next, as shown in FIG. 4(b), the epitaxial portion 202 and the metal barrier portion 204 are etched by an inductively coupled plasma (ICP) etching process using the metal mask layers 205a as etch masks, so as to form a pattern of at least one etched channel and at least one metal barrier layer 204a. Therefore, a plurality of epitaxial layers 202a and a plurality of metal barrier layers 204a are formed, and an etched channel is formed between adjacent epitaxial layers 202a. As the metal barrier layers 204a and the etched channels are fabricated by the same etching process, each metal barrier layer 204a completely wraps a corresponding reflection layer 203 and completely covers a surface of a corresponding epitaxial layer 202a. The reflection layer 203 has a light reflecting function, and may reflect light generated by the epitaxial layer 202a, so as to increase the luminous efficiency. Moreover, the epitaxial layer 202a and the epitaxial portion 202 may include, but not limited to, an N-type semi-conductive layer, an active layer and a P-type semi-conductive layer. The structures of the epitaxial portion and the epitaxial layer may be homostructures, single heterostructures, double heterostructures, multiple quantum well structures or any combination thereof. The materials of the metal barrier layer 204a and the metal barrier portion 204 are flexible metals, so as to prevent cracking of edges of the epitaxial layer 202a due to a gas pressure produced by dissociation of the epitaxial layer 202a in the laser lift-off process. The material of the reflection layer 203 includes nickel, silver, platinum, gold or a combination thereof.

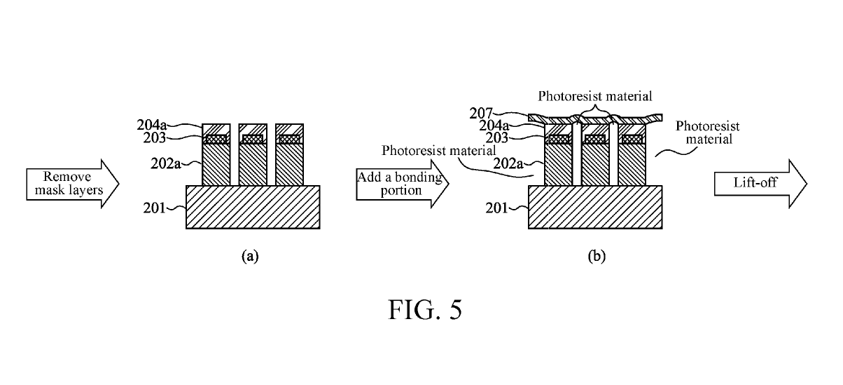

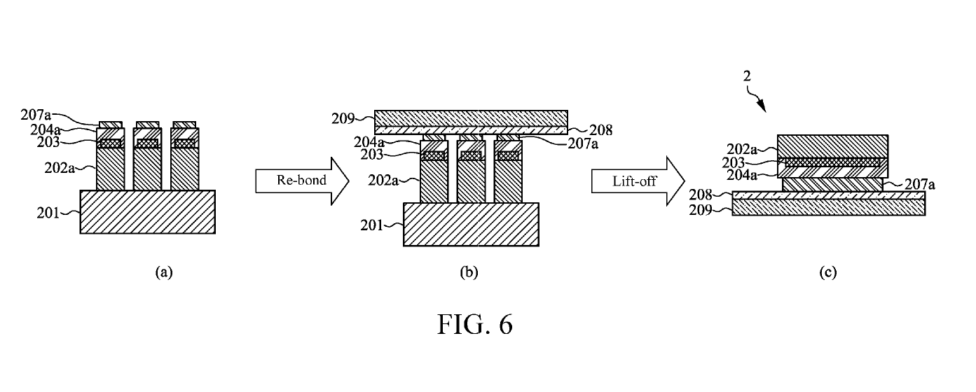

Next, as shown in FIG. 5(a), the metal mask layers 205a are removed, a pattern is formed from a negative photoresist and filled into the etched channels, and then a first bonding portion 207 is plated on the metal barrier layer 204a and the photoresist pattern by evaporation or sputtering. Next, as shown in FIG. 6(a), the photoresist and the first bonding portion 207 formed on the photoresist are removed by a lift-off technique, so as to form patterned first bonding layers 207a. When the photoresist is formed in the lift-off process, the photoresist pattern is slightly larger than the etched channel due to technical limitations of the lithography process. In this case, to prevent the subsequently formed first bonding portion 207 from extending into the etched channel, the first bonding layer 207a is slightly smaller than the metal barrier layer 204a and the epitaxial layer 202a.

As shown in FIG. 6(b), a second substrate 209 plated with a second bonding layer 208 is provided, and then the second bonding layer 208 of the second substrate 209 is bonded to the first bonding layer 207a, so as to bond the second substrate 209 to the epitaxial layers 202a by thermal bonding. Next, the first substrate 201 is removed by a laser lift-off (LLO) technique or polishing technique, so as to form a light emitting diode. Moreover, according to actual demands, the second bonding layer 208 and the second substrate 209 may further be cut, so as to obtain a light emitting diode of a required dimension. In addition, the materials of the first bonding portion 207, the first bonding layer 207a and the second bonding layer 208 include gold, silver, lead, tin, indium, an electrically conductive glue or a combination thereof. The material of the first substrate includes sapphire, gallium nitride (GaN), aluminum nitride (AlN), silicon carbide (SiC) or gallium aluminum nitride (GaAlN). The material of the second substrate is preferably an electrically conductive substrate with high thermal conductivity, so as to facilitate fabrication of a light emitting diode having a vertical structure. The material of the second substrate includes gallium nitride (GaN), silicon carbide (SiC) or silicon (Si).

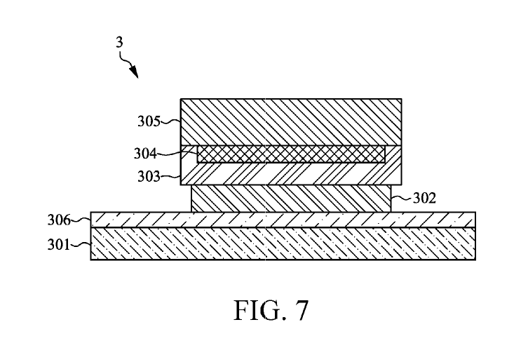

FIG. 7 shows a light emitting diode 3 according to one embodiment of the present invention. The light emitting diode 3 includes a substrate 301, a first bonding layer 302, a metal barrier layer 303, a reflection layer 304 and an epitaxial layer 305. The first bonding layer 302 is formed on the substrate 301, the metal barrier layer 303 is formed on the first bonding layer 302, the epitaxial layer 305 is formed on the metal barrier layer 303, and a surface of the epitaxial layer 305 is completely covered by the metal barrier layer 303. The substrate 301 further includes a second bonding layer 306, for being bonded to the first bonding layer 302. The reflection layer 304 is disposed between the epitaxial layer 305 and the metal barrier layer 303, and is wrapped by the metal barrier layer 303. The epitaxial layer 305 may include, but not limited to, an N-type semi-conductive layer, an active layer and a P-type semi-conductive layer. The structure of the epitaxial layer 305 may be a homostructure, a single heterostructure, a double heterostructure, a multiple quantum well structure or any combination thereof The material of the metal barrier layer 303 is a flexible metal, for example, a tungsten titanium alloy, platinum, tungsten or a combination thereof. As the metal barrier layer 303 may completely wrap the surface of the epitaxial layer 305, the gas pressure produced when the epitaxial layer 305 is dissociated by laser irradiation is borne by the epitaxial layer 305 and the metal barrier layer 303 at the same time, which may effectively alleviate the pressure produced against the epitaxial layer 305 in the laser lift-off process, thereby protecting the epitaxial layer 305 and preventing edges of the epitaxial layer 305 from cracking in the laser lift-off process. The material of the reflection layer 304 includes nickel, silver, platinum, gold or a combination thereof, and the reflection layer 304 has a light reflecting function, and may reflect light generated by the epitaxial layer 305, so as to increase the luminous efficiency. The materials of the first bonding layer 302 and the second bonding layer 306 include gold, silver, lead, tin, indium, an electrically conductive glue or a combination thereof. The material of the substrate 301 includes gallium nitride (GaN), silicon carbide (SiC) or silicon (Si).

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A method for fabricating a light emitting diode, comprising:
providing a first substrate, and forming an epitaxial portion on the first substrate;
forming at least one reflection layer on the epitaxial portion;
forming a metal barrier portion on the reflection layer;
etching the epitaxial portion and the metal barrier portion by a first etching process, so as to form a plurality of epitaxial layers and a plurality of metal barrier layers, wherein an etched channel is formed between adjacent epitaxial layers, and each metal barrier layer wraps a corresponding reflection layer and completely covers a surface of a corresponding epitaxial layer;
forming a first bonding layer on the metal barrier layer; and
forming a second substrate on the first bonding layer, and removing the first substrate.

2. The method for fabricating a light emitting diode according to claim 1, wherein before the step of forming the first bonding layer, the method further comprises:
forming a metal mask portion on the metal barrier portion;
forming at least one patterned photoresist layer on the metal mask portion by a lithography process;
etching the metal mask portion with an etchant and using the patterned photoresist layer as an etch mask, so as to form at least one metal mask layer, wherein each metal mask layer has an isolation trench;
forming the at least one epitaxial layer and the at least one metal barrier layer by using the metal mask layer as an etch mask of the first etching process; and
removing the metal mask layer on each metal barrier layer.

3. The method for fabricating a light emitting diode according to claim 2, wherein the etchant is a mixture of sulfuric acid, hydrogen peroxide and water.

4. The method for fabricating a light emitting diode according to claim 1, wherein the first etching process is an inductively coupled plasma (ICP) etching process.

5. The method for fabricating a light emitting diode according to claim 2, wherein the materials of the metal mask portion and the metal mask layer comprise nickel.

6. The method for fabricating a light emitting diode according to claim 1, further comprising:
patterning the first bonding layer by a lift-off technique when forming the first bonding layer, so that each first bonding layer is corresponding to each epitaxial layer and each metal barrier layer, wherein the first bonding layer is slightly smaller than the metal barrier layer.

7. The method for fabricating a light emitting diode according to claim 1, wherein before the second substrate is bonded to the first bonding layer, a second bonding layer is formed on the second substrate, for being bonded to the first bonding layer.

8. The method for fabricating a light emitting diode according to claim 1, wherein the materials of the metal barrier portion and the metal barrier layer comprise a tungsten titanium alloy, platinum, tungsten or a combination thereof.

9. The method for fabricating a light emitting diode according to claim 1, wherein the material of the reflection layer comprises nickel, silver, platinum, gold or a combination thereof.

10. The method for fabricating a light emitting diode according to claim 7, wherein the materials of the first bonding layer and the second bonding layer comprise gold, silver, lead, tin, indium, an electrically conductive glue or a combination thereof.

11. The method for fabricating a light emitting diode according to claim 1, wherein the structures of the epitaxial portion and the epitaxial layer are homostructures, single heterostructures, double heterostructures, multiple quantum well structures or any combination thereof.

12. The method for fabricating a light emitting diode according to claim 1, wherein the material of the first substrate comprises sapphire, gallium nitride, aluminum nitride, silicon carbide or gallium aluminum nitride, and the material of the second substrate comprises gallium nitride, silicon carbide or silicon.

13. A light emitting diode, comprising:
a substrate;
a first bonding layer, formed on the substrate;
a metal barrier layer, formed on the first bonding layer; and
an epitaxial layer, formed on the metal barrier layer,
wherein a surface of the epitaxial layer is completely covered by the metal barrier layer, and the first bonding layer is slightly smaller than the metal barrier layer.

14. The light emitting diode according to claim 13, further comprising:
a second bonding layer, formed between the substrate and the first bonding layer, for being bonded to the first bonding layer.

15. The light emitting diode according to claim 13, further comprising:
a reflection layer, disposed between the epitaxial layer and the metal barrier layer, and wrapped by the metal barrier layer.

16. The light emitting diode according to claim 13, wherein the material of the metal barrier layer comprises a tungsten titanium alloy, platinum, tungsten or a combination thereof.

17. The light emitting diode according to claim 15, wherein the material of the reflection layer comprises nickel, silver, platinum, gold or a combination thereof

18. The light emitting diode according to claim 13, wherein the material of the first bonding layer comprises gold, silver, lead, tin, indium, an electrically conductive glue or a combination thereof.

19. The light emitting diode according to claim 14 wherein the material of the second bonding layer comprises gold, silver, lead, tin, indium, an electrically conductive glue or a combination thereof.

20. The light emitting diode according to claim 13, wherein the material of the substrate comprises gallium nitride, silicon carbide or silicon.
